(19) United States
(12) Patent Application Publication
(10) Pub. No.: US 2013/0160824 A1
(43) Pub. Date: Jun. 27, 2013

(54) ROOF INTEGRATED SOLAR MODULE ASSEMBLY

(71) Applicants: Bruce Khouri, Glendale, CA (US); Mark Ensor, San Jose, CA (US)

(72) Inventors: Bruce Khouri, Glendale, CA (US); Mark Ensor, San Jose, CA (US)

(73) Assignee: SoloPower, Inc., San Jose, CA (US)

(21) Appl. No.: 13/492,702

(22) Filed: Jun. 8, 2012

Related U.S. Application Data
(63) Continuation-in-part of application No. 13/333,966, filed on Dec. 21, 2011.

(51) Int. Cl. H01L 31/048; E04B 7/00; E04D 13/18

(52) U.S. Cl. 136/251; 52/745.21; 52/745.06

(57) ABSTRACT

A solar module having a curved surface to facilitate shedding of accumulated snow and water. The module can also be angled to achieve the same. The module includes a housing with a curved or angled upper surface and solar cells are positioned within the housing.

### RELATED APPLICATIONS

This application is a Continuation in Part of U.S. application Ser. No. 13/333,966 filed Dec. 21, 2011 entitled INTEGRATED STRUCTURAL SOLAR MODULE AND CHASSIS.

### BACKGROUND

1. Field of the Inventions

The present inventions generally relate to solar panels and, more particularly, to design and manufacturing of solar panels including flexible thin film solar cells and solar panel assemblies including such solar panels.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂ is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or a contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate, such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Contrary to CIGS and amorphous silicon cells, which are fabricated on conductive substrates such as aluminum or stainless steel foils, standard silicon solar cells are not deposited or formed on a protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell.

Interconnected solar cells may then be packaged in protective packages to form modules. Each module typically includes a plurality of solar cells which are electrically connected to one another. Many modules can also be combined to form large solar panels. The solar modules are constructed using various packaging materials to mechanically support and protect the solar cells in them against physical and chemical damage, especially against moisture. The most common packaging technology involves lamination of circuits in transparent layers. In a lamination process, in general, the electrically interconnected solar cells are first covered with a transparent and flexible encapsulant layer. A variety of materials are used as encapsulants, for packaging solar cell modules, such as ethylene vinyl acetate copolymer (EVA), thermoplastic polyurethanes (TPU), and silicones. However, in general, such encapsulant materials are moisture permeable; therefore, encapsulated cells are placed into an outer shell which further seal the solar cells from the environment and forms resistance to moisture transmission into the module. The outer shell typically includes a top transparent protective sheet and a bottom protective sheet sandwiching the encapsulated solar cells while exposing the light receiving front surface of the solar cells through the top transparent protective sheet. An edge sealant seals the periphery of the top and bottom protective sheets, thereby completing the module or panel construction. The top protective sheet is typically transparent glass which is water impermeable and the back protective sheet can be a glass sheet or a polymeric sheet with or without a moisture barrier layer, e.g., an aluminum film, in it. The top and bottom protective sheets are conventionally flat, which give the flat shape to the module, to expose the front surfaces of the solar cells to sun light.

In general, solar modules or panels are secured on rooftops, often on roof shingles or other varieties of rooftop structures, to directly expose them to unobstructed sunlight. However, flat glass top sheets of solar panels must provide enough strengths to meet snow load requirements. In order to meet this requirement, the manufacturers use thicker and stress-free or tempered flat glass sheets as the top protective sheet to protect the encapsulated sensitive solar cells. Although the added thickness improves the strength of the flat glass sheet, the weight associated with the increased thickness of the glass has its own drawbacks. One of the drawbacks is the high cost of installing such heavy panels on the rooftops, and possible high cost of rooftop modifications to prepare the rooftop for such heavy weight, especially when a plurality of panels are required. Such modifications may require penetrating installations to better anchor the heavy panels to the roof top, which can make the rooftop less weather resistant by disturbing the rooftop's original sealed structure. Furthermore, the heavy weight of such modules limits the deployment of them on the rooftops that cannot carry such heavy loads.

From the foregoing, there is a need for glass based solar panels providing enough strength with reduced weight that can be deployed in short time and reduced cost.

### SUMMARY

The aforementioned needs are satisfied by embodiments of the present invention which, in a solar module assembly comprises a solar module having a convexly curved or angled plate like body defined by a curved or angled transparent top layer of the solar module disposed over a curved or angled bottom layer of the solar module, wherein a plurality of solar cells are disposed between the curved or angled transparent top layer and the curved or angled bottom layer such that light receiving sides of the solar cells face the curved or angled transparent top layer; and a curved or angled support to retain the curved or angled solar module, the curved or angled support including a curved or angled support top surface that substantially contacts and conforms to the curved or angled bottom layer of the solar module.

The solar module may also comprise a plurality of solar cells and a solar module body having a top transparent layer and a bottom layer and first and second lateral edges, wherein the transparent layer and bottom layer define a space that receives the plurality of solar cells and wherein a portion of the top transparent layer is elevated with respect to the first and second lateral edges to facilitate snow and water sliding off of the top transparent layer towards the first and second lateral edges.

In one aspect, the aforementioned needs are satisfied by a method of installing a rooftop solar system on a roofing surface comprising affixing an array of base elements including a plurality of fastening members to the roofing surface engaging feet of a module support with the plurality of fastening members of base elements so as to fasten the module support to the base elements on the roofing surface, wherein the module support having a top surface that is convexly curved or angled along a longitudinal axis of the top surface, and wherein the top surface includes a major surface portion that is generally separated from a minor surface portion along the longitudinal axis of the top surface. In this aspect, the method also comprises attaching a flexible solar module onto the top surface of the module support, the flexible module having a plate like body defined by a top transparent layer disposed over a bottom layer, wherein the bottom layer of the solar module is in physical contact with and is substantially supported by the top surface of the module support by covering the major surface and partially covering the minor surface of the top surface so as to leave an exposed access space on the minor surface.

In another aspect the aforementioned needs are satisfied by a solar module assembly installed on an application surface, comprising at least two base elements affixed to the application surface, the base elements including a bottom surface and an upper surface, wherein the upper surface includes a plurality of fastening members. In this aspect, the solar module further comprises a module support fastened to the base elements by engaging feet of the module support with the plurality of fastening members, the module support having a top surface that is convexly curved or angled along a longitudinal axis of the top surface, wherein the top surface includes a major surface portion that is generally separated from a minor surface portion along the longitudinal axis of the top surface. In this aspect, the module further comprises a flexible solar module attached onto the top surface of the module support, the flexible module having a plate like body defined by a top transparent layer disposed over a bottom layer, wherein the bottom layer of the solar module is in physical contact with and is substantially supported by the top surface of the module support by covering the major surface and partially covering the minor surface of the top surface so as to leave an exposed access space on the minor surface.

In another aspect, the aforementioned needs are satisfied by a solar module assembly comprising a first support member that defines a support surface having a length and a lateral width that is adapted to be positioned on a mounting surface, wherein the first support member extends outward from the mounting surface and wherein the support member is shaped so as to define a first elevated surface and a second elevated surface that intersect at an apex defining the height of the elevated surfaces. The solar module assembly further comprises a first flexible solar module that is mounted on the first support member so as to extend over at least some of the first elevated surface and a securing assembly that secures the first support member to the mounting surface.

In another aspect, the aforementioned needs are satisfied by a solar module assembly comprising a first module support member that defines a support surface with an elevated surface having a length and a lateral width that is adapted to be positioned on a mounting surface, wherein the first support member extends outward from the mounting surface and a first flexible solar module that is mounted on the first support member so a to extend over at least one of the first elevated surfaces. In this aspect the module also comprises a securing assembly that secures the first support member to the mounting surface wherein the first module support member has first and second foot members at the ends of the first module support member that secure the first support member to the mounting surface; and a plurality of support members that engage with the first module support member so as to extend between the first module support member and the mounting surface, wherein the plurality of support members extend in rows across the lateral width of the elevated surface.

### BRIEF DESCRIPTION OF THE DRAWINGS

FIG. 1 is a schematic illustration of a solar cell;

FIG. 2 is a schematic illustration of a curved solar module supported by a curved module support;

FIG. 3 is a schematic cross-sectional illustration of the curved solar module shown in FIG. 2;

FIG. 4 is a schematic exploded view of a solar assembly embodiment including a curved solar module and an embodiment of a curved support frame;

FIG. 5 is a schematic frontal side view of the solar assembly installed on a surface;

FIG. 6 is a schematic illustration of an embodiment of attaching edges of the curved solar module to the curved support frame;

FIG. 7 is a schematic illustration of a front portion of the solar assembly after the edges of the curved module has been attached to the curved support frame;

FIG. 8 is a schematic exploded view of another solar assembly embodiment including a curved solar module and another embodiment of a curved support frame;

FIG. 9 is a schematic frontal side view of the solar assembly installed on a surface;

FIG. 10 is a schematic illustration of an embodiment of attaching edges of the curved solar module to the curved support frame;

FIG. 11 is a schematic illustration of an angled solar module supported by an angled module support;

FIG. 12 is a schematic cross-sectional illustration of the angled solar module shown in FIG. 11;

FIGS. 13A-14C are schematic illustrations of embodiments of a module assembly;

FIG. 15 is a schematic illustration of an embodiment of a curved module support;

FIG. 16A is a schematic illustration of an embodiment of a module assembly fastened on an application surface, wherein a solar module is fastened to a curved module support;

FIG. 16B is a schematic illustration of an embodiment of a module assembly in perspective view;

FIG. 16C is a schematic illustration of an embodiment of a curved module support of the module assembly shown in FIGS. 16A and 16B;

FIGS. 17A-17D are schematic illustrations of various curved module support embodiments;

FIG. 18 A is a schematic illustration of a method of installing a module assembly on an application surface in exploded view;

FIG. 18B is a schematic illustration of a portion of a base element with fastening members;

FIG. 19 is a schematic illustration of a method of fastening two module assemblies to a base member that is fastened to an application surface;

FIG. 20 is a schematic illustration of an array of module assemblies in top view;

FIGS. 21A-23B are schematic illustrations of various module supports and module assemblies;

FIGS. 24A-24B are schematic illustrations of an embodiment of a module assembly;

FIGS. 25A-25B are schematic illustrations of an embodiment of a module assembly;

FIGS. 26A-26B are schematic illustrations of an embodiment of a module assembly; and

FIG. 27A-27C are schematic illustrations of module supports and module assemblies.

### DETAILED DESCRIPTION OF THE PREFERRED EMBODIMENTS

The preferred embodiments described herein provide a solar module including a curved or angled module body or shell defined by a convexly curved or angled top transparent layer and a bottom layer which may be curved or angled and which may conform to the shape of the top transparent layer. The curved or angled transparent top layer is placed over the bottom layer, and a plurality of solar cells is disposed between the top transparent layer and the bottom layer. The plurality of solar cells includes a light receiving side facing the top transparent layer. Curvature or angling of the module provides structural strength to the module without increasing its weight, thereby allowing maximum snow load and facilitating shedding of water, snow or other precipitation. In another embodiment of the present invention a solar module assembly including the convexly curved or angled module and a curved or angled support frame or chassis to retain the solar module is provided. In one embodiment, the curved or angled support frame may include a curved or angled top surface that substantially contacts and conforms to the curved or angled bottom layer of the solar module. The solar module assembly may further include attachment elements or feet on the opposite side of the curved or angled top surface of the curved or angled support frame to install the solar module assembly on an application surface such as a rooftop. The curved or angled support frame provides the module structural integrity by mechanically supporting it. The curved or angled shape of the support elevates the module off the rooftop, thereby allowing air flow beneath the curved or angled module, which optimizes module's thermal performance by acting as a cooling source. The curved or angled module support may be configured with a symmetrical top surface having a saddle shape or an asymmetrical top surface having a wedge shape to support the solar module.

FIG. 2 shows an exemplary solar module assembly 90 of the present invention including a solar module 100 supported by a support 102. The solar module includes a plurality of solar cells 105 depicted with dotted lines in FIG. 2. The solar module has a convexly curved body that may be curved along a longitudinal axis or L-axis, of the solar module 100. In one embodiment, the curved body of the solar module 100 may be a curved rectangular body that extends along the L-axis such that long edges 104A of the solar module 100 extend parallel to the L-axis and between curved edges 104B which may have the same curvature. In this embodiment, the module is held and supported by the support 102 which is also convexly curved and extending along the L-axis of the curved module and thus conforms to the convexly curved shape of the solar module 100. The support 102 may be a continuous support comprising a single support surface extending and covering the full bottom surface of the curved solar module 100 or a discontinuous support comprising a number of integrated support surfaces supporting the full bottom surface of the curved solar module at selected bottom surface sections. In one implementation, the long edges 104A and the curved edges 104B of the solar module are aligned with long edges 106A and curved edges 106B of the support 102 respectively as in the manner shown in FIG. 2. As will be described more fully below, depending on the use, the design and structure of the support 102 may vary.

FIG. 3 shows a detail view of the convexly curved cross section of the solar module 100 shown in FIG. 2. In this view the L-axis is perpendicular to the plane of the paper or parallel to the y-axis of the 3-D coordinate system shown in FIG. 3. It is understood that the structure of module 100 is examplary and demonstrative and is drawn for the purpose of showing various aspects of the present inventions. As also shown in FIG. 2, the module 100 comprises examplary solar cells 105 which may be electrically interconnected in series using conductive leads (not shown). It is possible that the solar cells 105 may be shingled and, therefore, there may be no conductive leads interconnecting them. The solar cells may be flexible solar cells or curved solar cells which may have a curvature complying with the curvature of the module. The interconnected cells are connected to a junction box located outside the module 100. The junction box may be located in or be an integral part of the support 102. The electrically interconnected solar cells or so called solar cell strings are covered with a transparent and flexible encapsulant layer 110 which fills any hollow space among the cells and tightly seals them, preferably covering both of their surfaces. A variety of materials are used as encapsulants for packaging solar cell modules such as ethylene vinyl acetate copolymer (EVA) and thermoplastic polyurethanes (TPU). The encapsulated solar cells are further sealed from the environment by a protective shell 112, which forms a barrier against moisture transmission into the module package. The protective shell of the module includes a top transparent layer 114 or top transparent sheet and a bottom layer 116 or bottom sheet and an edge sealant 118 extending between the top protective sheet and the bottom protective sheet. The water vapor transmission rate of the edge a sealant is preferably below 0.001 gm/m²/day, more preferably below 0.0001 gm/m²/day.

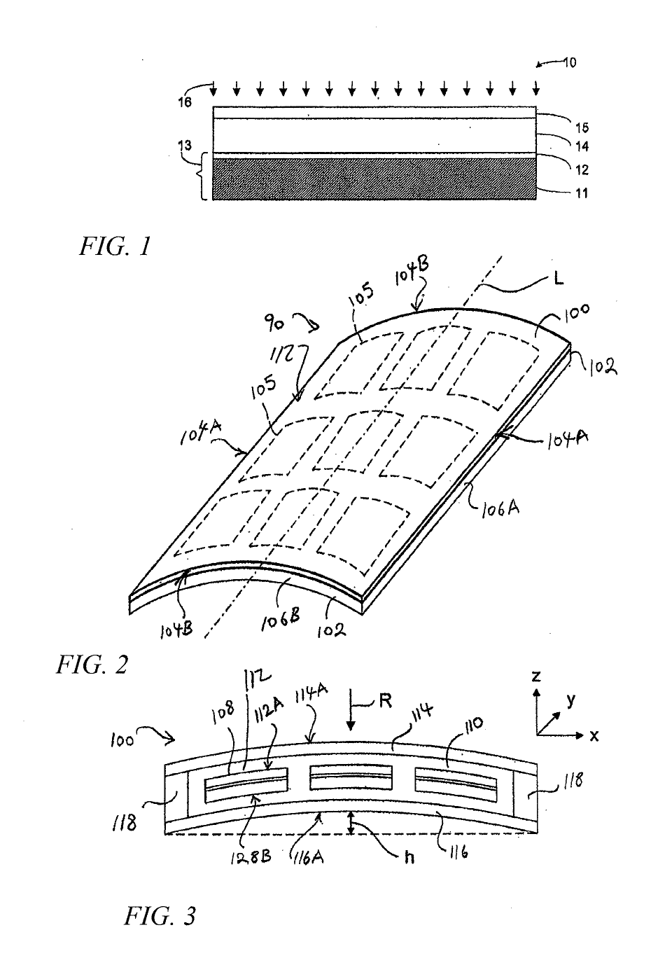

In the module 100, each solar cell 105 includes a front light receiving side 119A facing toward the top transparent layer 114 and a back side 128B facing towards the bottom layer 116 of the module. The solar cells 105 may be conventional CIGS based thin film solar cells, which are exemplified in FIG. 1. The front light receiving side 119A includes an absorber layer and a transparent layer deposited over the absorber layer. The absorber layer may be a Group IBIIIAVIA compound semiconductor layer such as a Cu (Ga, In) (Se, S)₂ thin film or CIGS. The transparent layer may include a stack including a buffer layer such as a CdS layer deposited over the absorber layer and a transparent conductive oxide (TCO) layer such as a ZnO layer deposited over the buffer layer. The back side 128B of each solar cell 105 includes a substrate and a contact layer.

Referring back to FIG. 3, in one embodiment, the top transparent layer 114 and the bottom layer 116 of the module 100 have a convexly curved shape. As shown in FIG. 3, the top transparent layer 114 is placed over the bottom layer 116 which conforms to the curvature of the top transparent layer. The distance between the top transparent layer 114 and the bottom layer 116 does not change throughout the module body; therefore the radial distance formed between a top outwardly curved surface 114A and a bottom inwardly curved surface 116A of the module 100 is the same predetermined distance or the thickness of the module 100. In one embodiment, the convexly curved top transparent layer and the bottom layer may be shaped as an arc having an arc-height, or arc-depth, from 10 mm to 200 mm from peak of arc to the midpoint perpendicular to chord of the arc shown in dotted lines in FIG. 3. The arc of the curved edges 106B of the support 102 shown in FIG. 2 may also have the same arch-height ‘h’.

In one implementation, the top transparent layer 114 having the desired convexly curved shape may be a curved glass layer or sheet, such as a tempered glass sheet, or it may also be a curved transparent flexible polymer film such as TEFZEL® from DuPont, polyethylene terephthalate (PET), polyethylene naphthalate (PEN) or another polymeric film with moisture barrier coatings. The bottom layer 116 may be a curved sheet of glass or a curved polymeric sheet such as TEDLAR®, or another polymeric material which may or may not be transparent.

In another embodiment, the module 100 may have a flexible flat body made of the above exemplified flexible polymer sheets. The convexly curved shape of the flexible module is formed when the flexible module is applied and retained on the curved support, for example, as shown in FIG. 2. For both embodiments, the curvature of the module 100 provides multiple functions including but not limited to structural rigidity, elevation, cooling, show loading, water shedding, water flow through, air flow disruption, junction box and cable UV shielding.

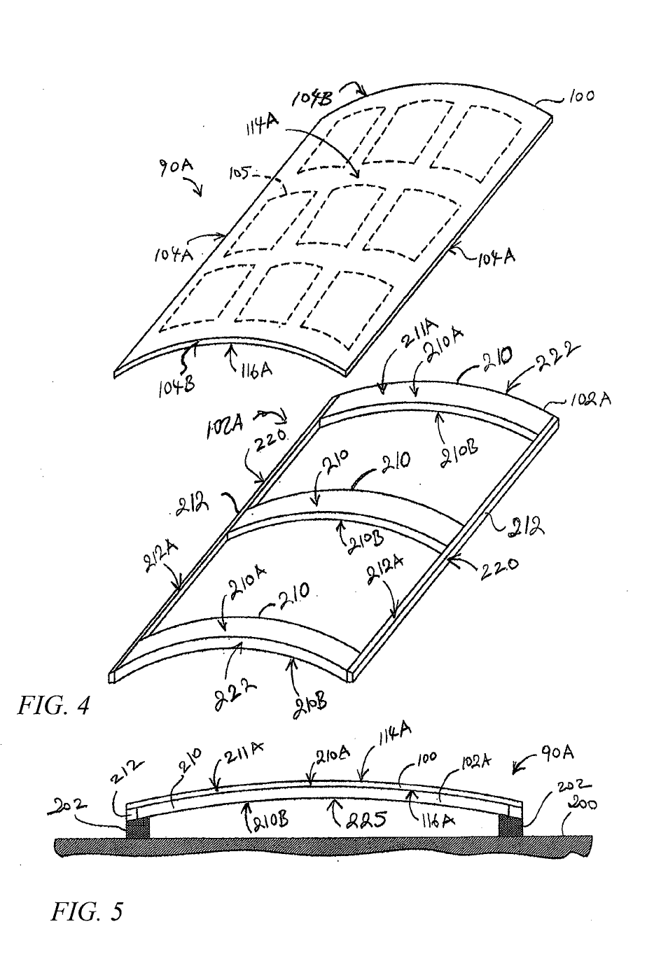

FIGS. 4 through 10 show various solar module assembly embodiments employing the module 100 described above and various support embodiments. As shown in FIG. 4 in an exploded view, an embodiment of a solar module assembly 90A includes the curved solar module 100 described in FIGS. 2 and 3 and a support frame 102A or chassis. FIG. 5 shows a frontal view of the assembly when installed on an application surface 200 such as rooftop using attachment members 202 or feet.

The support frame 102A of the module assembly 90A includes a number of curved cross members 210 attached to at least two side members 212. The curved cross members 210 are curved sheet like strips with a desired thickness, each having curved top surface 210A and curved back surface 210B. The side and curved cross members may be made of metals (such as aluminum) or plastics (such as polycarbonates) adequate for long-term use and resistant to conditions prevalent in outdoor environments. Such conditions could be, but are not limited to, extreme temperature variations, mechanical stress caused by expansion and contraction of the module and chassis components due to temperature variations, exposure to the sun, exposure to fire, exposure to high loads such as caused by wind, rain, snow, hail, and installation, transportation, and repair handling. Cross members may be designed with sufficient thickness, such as +/−25 mm, to provide room for junction boxes (if applicable) such that solar panels can be stacked flat during shipping to maximize the number of panels that can be shipped at one time. Widths and lengths of cross members may be adjusted as appropriate for the length, width, and weight of module.

As shown in FIG. 4, in one implementation, three curved cross members 210, which may preferably be spaced equidistantly, extend between the side members 212. The side members extend parallel to the L-axis of the module 100. In this configuration, both the upper surfaces 210A of the curved cross members 210 and upper surfaces 212A of the side members 212 define a substantially discontinuous curved support surface 211A that the inwardly curved surface 116A of the curved module 100 conforms to. The support frame 102A provides a mechanically secure platform to deploy large curved modules onto residential and commercial/industrial rooftops. The support frame 102A is shaped and dimensioned to match the shape of the curved solar module 100, and when they are assembled together as in the manner shown in FIG. 5, the long edges 104A and the curved edges 104B of the curved solar module 100A may be aligned with long edges 220 and curved edges 222 of the support frame 102A, respectively. Exposed surface portions of the bottom inwardly curved surface 116A and the bottom surfaces 210B of the curved cross members 210 define a curved bottom wall 225 of the module assembly 90A. Due to its curved shape, the curved bottom wall 225 of the module assembly is elevated from the application surface and defines a large tunnel-like passage under the assembly. Such space allows air to flow under the assembly 90A to optimize the temperature of the module 100 held by the assembly. To increase the mechanical stability of the module assembly 90A, the attachment members 202 or feet may be secured to the side support members 212 at locations where the ends of the curved cross members 210 join to the side support members.

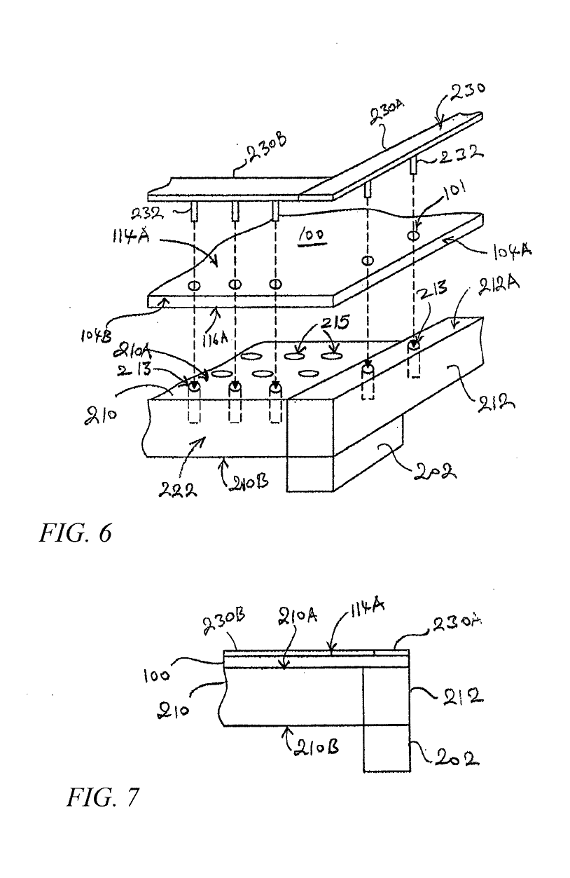

In the module assembly 90A, the curved solar module 100 can be attached to the support frame 102A using various fastening and bonding methods. As shown in FIG. 6 in a partial exploded view and in FIG. 7 in side view, in one embodiment, the curved support frame 102A includes first holes 213 formed vertically along the perimeter of the support frame in the side members 212 and the curved cross members 210. The curved support frame may optionally include second holes 215 or adhesive holes formed in the upper surface 210A of the curved cross members 210. The first holes 213 engage with module edge holders 230 or edge rail to capture or retain the perimeter of the solar module 100. There may be two side edge holders 230A to secure both long edges 104A of the module on both side members 212, and there may be two cross edge holders 230B to secure the curved edges 104B of the module on both curved cross members 210. For this purpose, an edge region of the module may include edge holes 101 formed adjacent the long edges 104A and the curved edges 104B. It is important that the edge holes 101 of the curved module 100 be formed without damaging the edge moisture sealant and preferably through an extended edge portion (not shown) of the curved module 100.

In one embodiment, to attach the curved module 100 onto the curved support frame 102A, firstly, if they are used, the second holes 215 may be filled with an adhesive and the curved module 100 is pressed against the adhesive filling the holes to attach and secure the body of the module 100 on the curved support frame 102A; secondly, pins 232 of the edge holder 230 are passed through the edge holes 101 of the curved module 100 and inserted into the first holes 213 to secure the edges 104A, 104B of the curved module 100. The pins 232 and the first holes 213 may have mating features to interlock and keep the pins 232 in the first holes 213, and thereby allowing the module edge holder to secure the edges 104A, 104B of the module on the support frame 102A. A strip 233 or clip portion of the module edge holder 230 seals the first holes 213 and further restrains the module edges on the support.

In an alternative embodiment, there may be used only two side edge holders 230A without the cross edge holders 230B. In this alternative approach, the adhesive holes including the adhesive may or may not be used. Holes or slots and pins are to be sized appropriate for resistance to environmental and mechanical loads stated previously and the material strengths of pin material and module materials. One such size is +/−5 mm diameter but the size is not limited to this. Adhesives, if used, provide resistance to water egress into the module materials and be resistant to the environmental conditions into which they will be exposed. Such materials are, but are not limited to Butyl based and Silicon based materials.

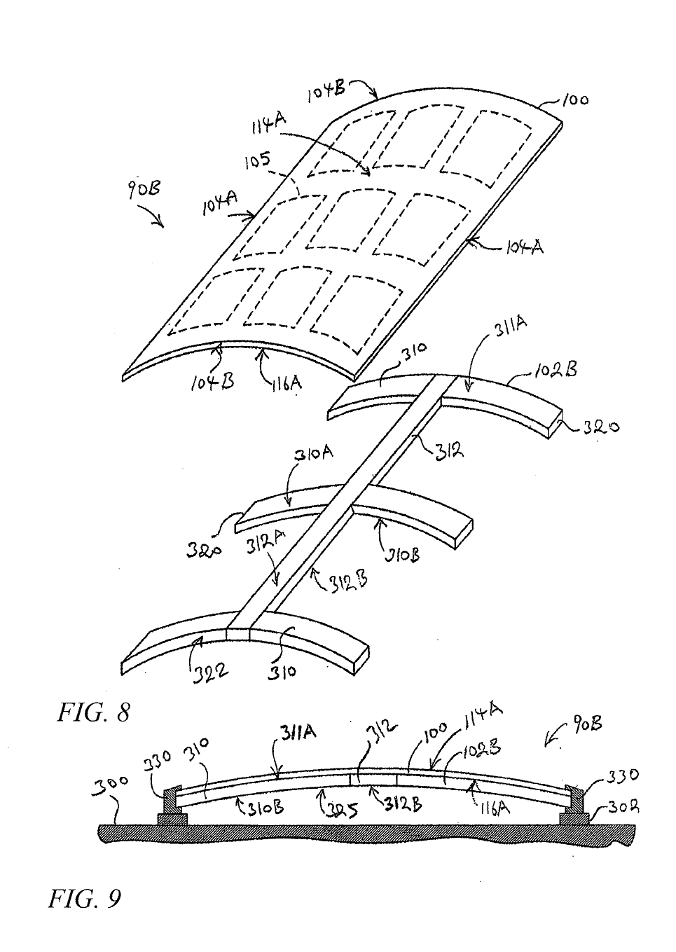

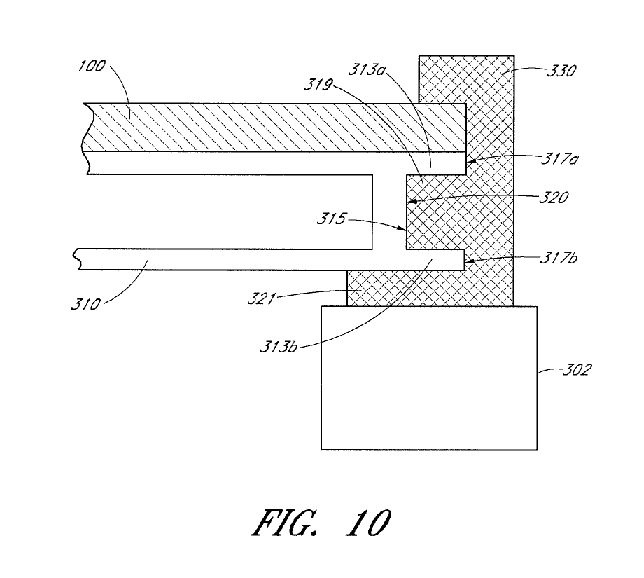

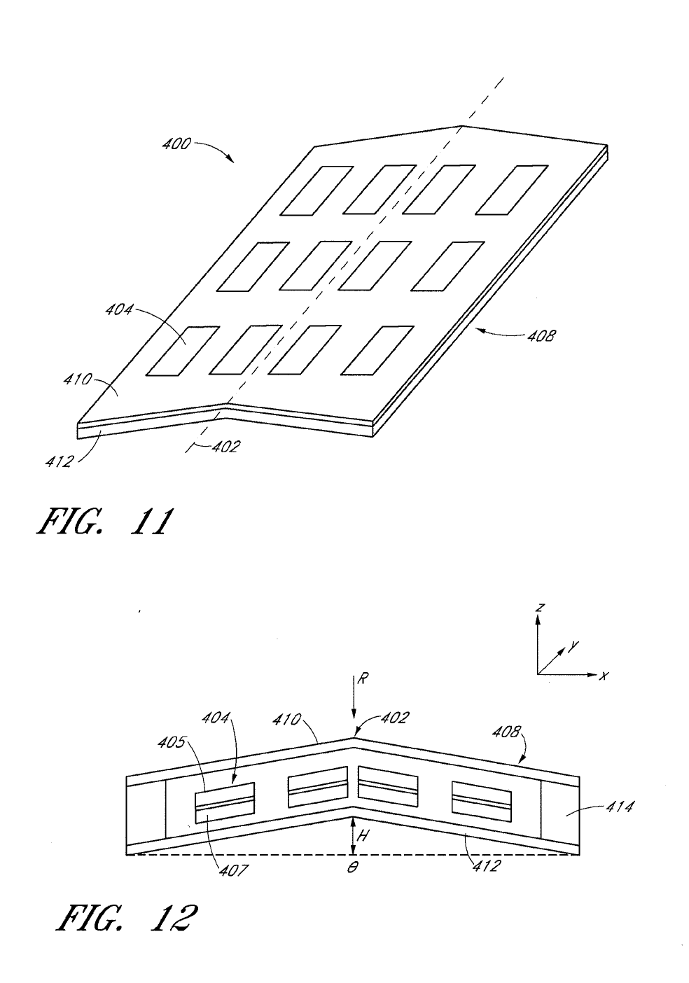

FIG. 8 shows in exploded view, another embodiment of a solar module assembly 90B including the curved solar module 100 described in FIGS. 2 and 3 and another support frame 102B or chassis. FIG. 9 shows a frontal view of the assembly when installed on an application surface 300 such as rooftop using attachment members 302 or feet.

The support frame 102B of the module assembly 90B includes a number of curved support members 310 or ribs attached to a center support member 312. The center support member 312 extends along the length of the curved solar module 100 and the plurality of attached support members extend outwardly in opposite directions from the center support member 312 so that both the upper sides of the center support member 312 and curved support members 310 define an elongated convex frame surface. The curved support members 310 are curved sheet like strips with desired thickness and each having a curved top surface 310A and a curved back surface 310B. As shown in FIG. 8, in one implementation, six curved support members 310, which may preferably be spaced equidistantly, extend from the center support member 312 such that both the upper surfaces 310A of the curved support members 310 and upper surface 312A of the center member 312 define a substantially discontinuous curved support surface 311A that the inwardly curved surface 116A of the curved module 100 conforms to. The support frame 102B provides a mechanically secure platform to deploy large curved modules onto residential and commercial/industrial rooftops as in the previous embodiment. The side and curved cross members may be made of metals (such as aluminum) or plastics (such as but not limited to polypropylenes or polycarbonates reinforced with glass fibers, UV and fire resistant additives) adequate for long-term use and resistant to conditions prevalent in outdoor environment. Cross members may be designed with sufficient thickness, such as +/−25 mm, to provide room for junction boxes (if applicable) such that solar panels can be stacked flat during shipping to maximize the number of panels that can be shipped at one time. Widths and lengths of cross members may be adjusted as appropriate for the length, width, and weight of module.

The support frame 102B is shaped and dimensioned to match the shape of the curved solar module 100, and when they are assembled together as in the manner shown in FIG. 5, long edges 104A and the curved edges 104B of the curved solar module 100 may be aligned with outer ends 320 and curved edges 322 of the support frame 102B, respectively. Further, exposed surface portions of the bottom inwardly curved surface 116A, the bottom surfaces 310B of the curved support members 310 and a bottom surface 312B of the center support member 312 define a curved bottom wall 325 of the module assembly 90B. Due to the its curved shape, the curved bottom wall 325 of the module assembly is elevated from the application surface and defines a large tunnel-like passage under the assembly. Such space allows air to flow under the module assembly 90B to regulate the temperature of the module 100 held by the assembly. To increase the mechanical stability of the module assembly 90B, the attachment members 302 or feet may be secured to the outer end 320 of curved support members 312. As shown in FIG. 10, in one embodiment, retainer members 330 are used with the attachment members 302 to hold the ends 320 of the curved support members 310 and the long edges 104A of the curved solar module 100 so as to hold the curved solar module 100 in engagement with the support frame 102B.

More specifically, as shown in FIG. 10, the curved support member 310 has two arms 313a, 313b that form an “H” shape and define an opening 315. The retainer member 330 includes two apertures 317a, 317b that receive the arms 313a, 313b and a protrusion 319 that extends into the opening 315. In this implementation, the retainer member 330 also includes a bottom support member 321 that extends past the H-shaped arms 313a, 313b and is interposed between the curved support member 310 and the attachment member 320. In this way, the curved support member 310 and the panels can thus be securely mounted. It will be appreciated that any of a number of different mounting structures can be used without departing from the spirit and scope of the present invention.

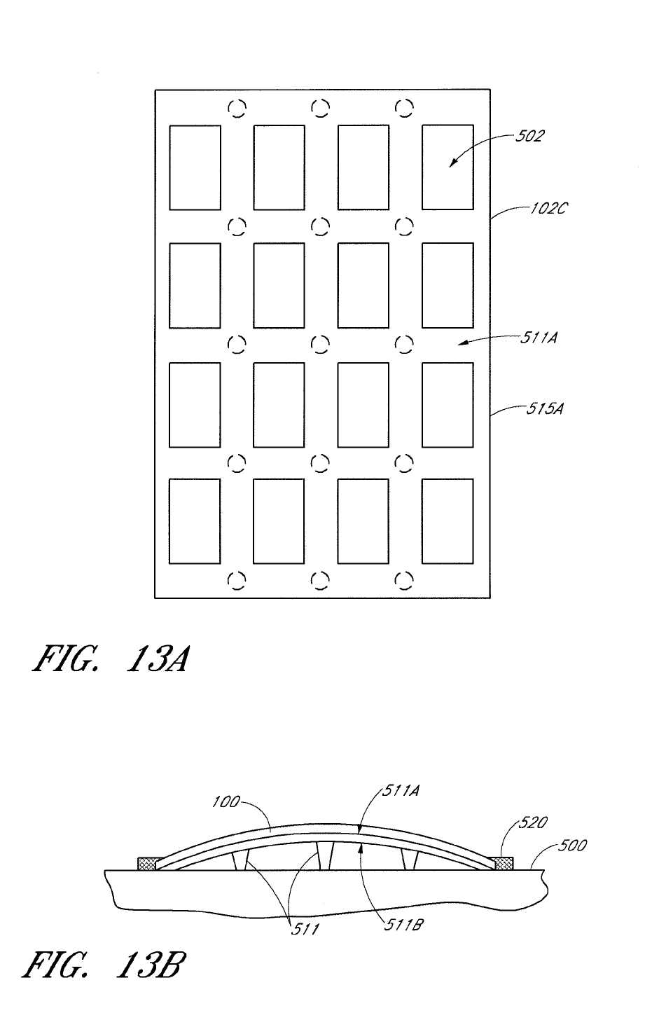

It will be appreciated that the solar module assembly can also be angled as opposed to curved in the manner shown in FIGS. 1-10. More specifically, as shown in FIGS. 11 and 12, the solar module 400 is preferably angled about a center axis 402. As discussed in greater detail below, the angle θ about the center axis 402 is selected so as to provide an angled surface to facilitate snow and water removal but still allow solar cells 404 to be exposed to the sun. In this implementation, the solar module 400 includes solar cells 404 having a substrate 405 and an absorber layer 407 that do not have to be curved but can be formed so as to be straight in the manner shown in FIG. 1. The solar cells 404 are encapsulated within the module 400 and have a protective shell 408 in the same manner having an upper transparent layer 410, a bottom surface 412, and side seals 414 as described above and is positioned on an angled support frame (not shown) that is similar to the curved support described above.

In both the curved and angled implementations, the center portion of the module is raised above the outer edges of the module by an amount h selected to provide a sufficient angle to facilitate snow and water running off of the panel while still allowing the solar cells to be directly exposed to the sunlight. It will be appreciated that one side of the solar panel will be directly facing the sun and the other curved or angled side will not be directly facing the sun. However, if the curvature or angling is not large enough to cause the solar panels to be shaded, the efficiency of the solar cells that are not directly facing the sun is not significantly diminished. The Applicant has determined that an angle within the range of approximately 2 degrees to 30 degrees or a radius of curvature within the range of approximately 2.2 meters to 7 meters provide a surface that is capable of shedding snow and water due to gravity which thereby enhances the efficiency of the solar module but does not significantly impact the solar efficiency of the cells that are not directly facing the sun.

It will be further appreciated that any of a number of different configurations of the module can be made that facilitate snow or water drainage from the solar module. So long as a center portion of the module is elevated with respect to the edges, the solar module can thus facilitate water removal while still permitting the solar cells within the module to directly receive sunlight. Thus, the center portion can be raised with respect to the edges by curving the module or angling the module in the manner described above.

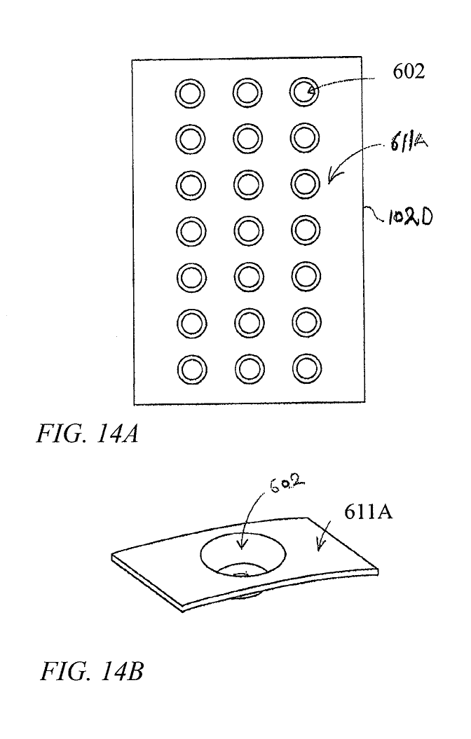

FIGS. 13A-14C show alternative curved support frame embodiments to retain the module 100 as described in the above curved module assembly embodiments. In these embodiments straight edges of the curved support frame may rest directly on the application surfaces without needing any additional feet or other support. The module on the support frame may be held by the retainer members secured on the application surfaces. The module may not be physically attached to the underlying support frame but may use it as a saddle. Alternatively, the module may be attached to the support frame as in the previous embodiments, and the support frame may be attached to the application surface. FIG. 13A shows a curved support frame 102C in top view, and FIG. 13B shows the curved support frame 102C assembled with the solar module 100 in frontal side view. The curved support frame 102C includes a number of openings 502 extending between a curved upper surface 511A or support surface and a curved bottom surface 511B. The openings 502 provide air flow for the module. In this embodiment the curved support frame 102C is supported on an application surface 500 by a plurality of legs 511 as well as long edges 515A that rest on the application surface 500. The legs 511 extend from the curved back surface 511B, and the long edges 515A of the of the support frame 102C are tapered to conform to the flat application surface. In one embodiment, the assembly may be held on the application surface 500 by capturing the long edges 515 of the module with retainer members 520, such as clamps, braces or fasteners secured on the application surface which securely hold the edges of the module supported by the support frame, and thereby securing the module assembly on the application surface.

FIG. 14A shows another curved support frame 102D in top view, and FIG. 14C shows the curved support frame 102D assembled with the solar module 100 in frontal side view. The curved support frame 102D includes a number of recesses 602 that function as legs for the curved support frame 102D while providing air circulation. As shown in FIG. 14B the recess 602 may have a round or cup shape formed in the upper curved surface 611A and may have an opening at the bottom. The curved support frame 102D is supported on an application surface 500 by both the recesses 602 and long edges 615A that rest on the application surface 500. The long edges 615A of the support frame 102D may also be tapered to conform to the flat application surface. As in the previous embodiment, the module-support frame assembly may be held on the application surface 600 by capturing the long edges 615A of the module with retainer members 620, such as clamps, braces or fasteners secured on the application surface which securely hold the edges of the module supported by the support frame, and thereby securing the module assembly on the application surface.

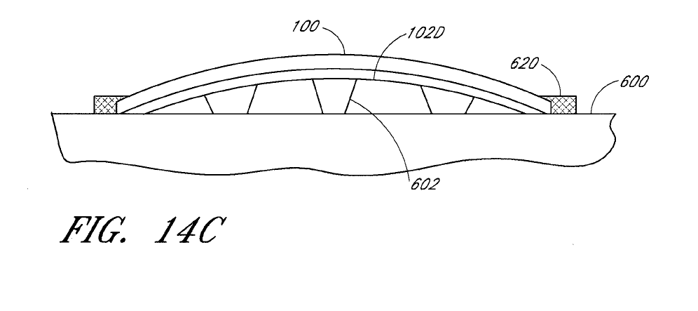

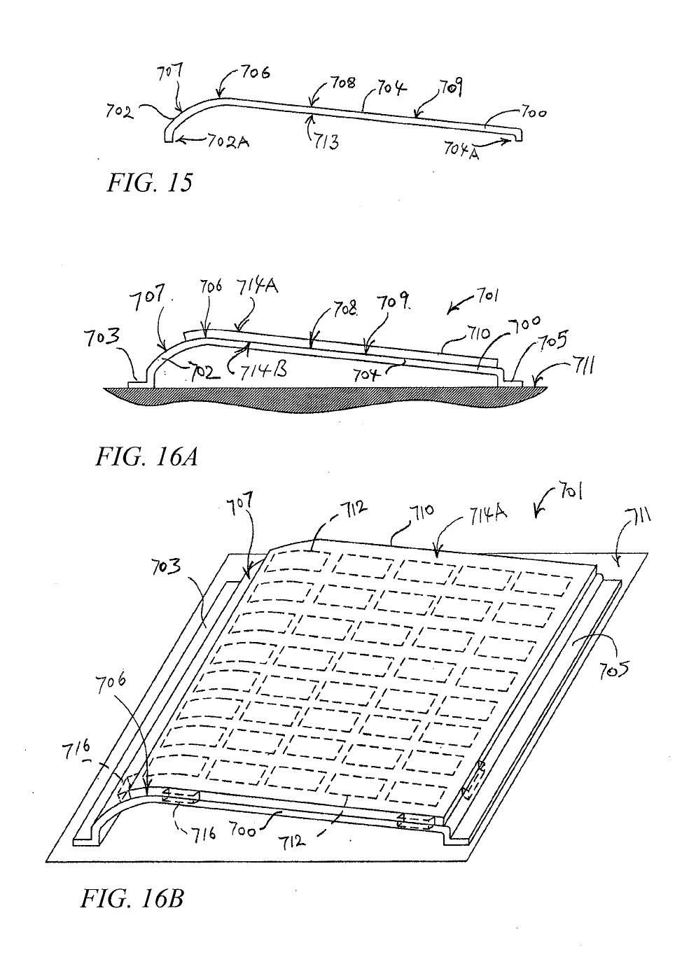

The following embodiments will describe a roof integrated solar module assembly or assembly kit. Referring now to FIG. 15, there is shown an embodiment of a wedge shaped module support frame 700 or module support in cross section. The module support 700 may be a panel or plate that has a generally convexly curved or arc-shaped body along a longitudinal axis of it. The module support 700 may include a front leg 702 integrally joining a rear leg 704 at an apex 706 or apex line which is disposed outwardly. It will be appreciated that, in this example, the rear leg 704 is of greater length than the front leg 702. Further, the support 700 includes a top surface 708 and a back surface 713. An upper surface portion 707 of the front leg 702 and an upper surface portion 709 of the rear leg 704 essentially define the top surface 708 of the support 700. The upper surface portions 707 and 709 will be referred to as minor surface portion and major surface portion of the support herein after. With the exception of optional use of various support members (to be described below), which may be integrally formed under the module support 700, the module support 700 is preferably of substantially uniform cross section throughout its longitudinal extent. The lower end 702A of the front leg portion 702 and the lower end 704A of the rear leg portion 704 may be used to fasten the support on an application surface, such as an external surface of a building like rooftop or walls; alternatively, the first and second legs themselves may serve this function.

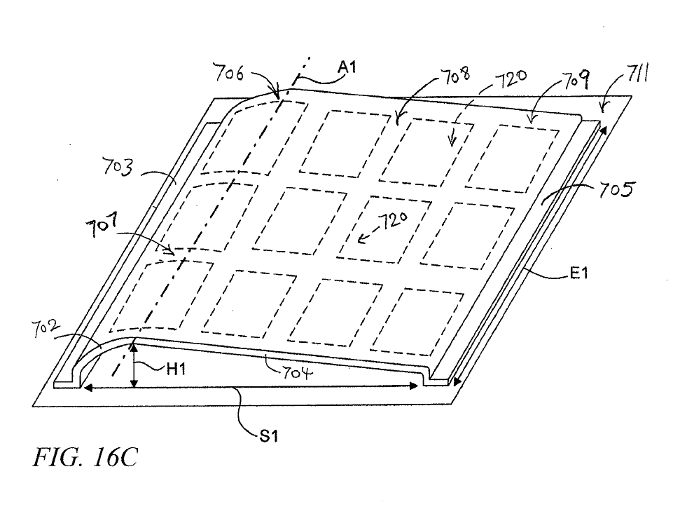

In FIG. 16A, there is shown a module assembly 701 including an embodiment of the support 700 with a module 710 mounted on the support. The support 700 of this embodiment may include a front foot member 703 and a rear foot member 705 to fasten the support 700 on an application surface 711 such as an external surface of a building like rooftops or walls. The application surface 711 may be a flat or curved surface positioned horizontally vertically or with an angle. The front and rear foot members 703, 705 may be flanges outwardly extending from the lower ends 702A, 704A of the front and rear legs 702 and 704. The front and rear foot members 703 and 705 form the front and rear edge of the support respectively, and are made parallel to the application surface 711 to balance and secure the support 700 on the application surface 711. This elevated configuration of the assembly 701 maintains module elevation off the application surface, such as a roof deck, to allow air and water flow-through it. It will be appreciated that depending on the application surface characteristics such as surface topography, the dimensions of the modules or the module supports may be varied, and as a result multiple modules may utilize a single module support, or multiple module supports may have a single solar module on them.

Referring to FIGS. 16A and 16B, a solar module 710 including a plurality of solar cells 712 is secured to the top surface 708 of the support 700 covering the top surface and engaging in its convex curvature. The solar cells 712 placed between a transparent front layer 714A and a back layer 714B of the solar module 710 and the edges of the module moisture sealed as described above. The top area of the module covered by the solar cells 712 is often referred to as an active area of the solar module. The module 710 may be a flexible solar module conformally or form-fittingly covering the top surface 708 partially or in its entirety. The solar cells 712 may be flexible solar cells that are built on flexible substrates. The flexible module 710 may be fastened to the top surface 708 of the support 700 using mechanical fasteners such as edge holders described above or adhesives or both. By applying, preferably, a fast hardening adhesive between the back layer 714B of the module 710 and the top surface 708 of the support 700 a secure and watertight bond between the module 710 and the support 700 is established. The exposed edges of the module 710 may also be chamfered with the fast hardening adhesive or other adhesive agent resulting in a stronger bond between the support 700 and the flexible module 710. Alternatively, the module 710 may be held on the support 700 by the edges of the module by capturing the edges by structures similar to module edge holders 230 shown in FIG. 6 above. Optionally, the adhesives and the edge holders may be used together to secure the module on the support.

The solar module 710 may be configured to have the same surface dimensions of the top surface 708 of the module support 700 or may be smaller then the top surface. In one embodiment, the module 710 fully covers the major surface portion 709 but partially covers minor surface portion 709 of the top surface 708 of the support 700 so as to define an exposed space 707A that permits access as discussed below. By pressing in the flexible module 710, the forward edge of it is bent over the apex line 706 towards the minor surface portion 709, and engage in the curvature of the top surface 708. Because of the flexibility of the solar cells, the flexible module 710 can be bent without damaging the solar cells 712 sealed within the module. The partially exposed portion 707A of the minor surface may be used as a walk way by the assembly crews when assembling or maintaining solar assemblies. Some of the several benefits of the flexibility of the module in this system include: The ability to optimize the shape of the module to maximize the exposure of the active area of the module to the sun while conforming to the lower profile shape of the structure to reduce its exposure to wind forces, increased toughness of the module during and after installation since it can be rolled into place and can be walked on during installation, and it is resistant to damage if it is dropped or not supported continuously.

This curved structure of the module assembly 701 allows for snow or rain water to run off without obstruction, preventing dirt forming particles from being deposited on top of the module obstructing sunlight. A junction box 716 of the module may be attached to the edges of the module (front, back or sides as shown in FIG. 16B). The junction box 716 may be hermetically sealed into the module and mechanically stable. Electrical cables (not shown) are attached to the junction box and may be extended along the edges of the module 710. The structure can also be used to keep the wires off the application surface, such as a roof decks, keeping them out of the water, protecting them from wind, and protecting them from exposure to the sun. This wiring path benefit can be extended to simplifying wiring in large arrays where circuit strings from remote strings inside large arrays can be carried by adjacent structures to the nearest accessible wire path trunk.

As shown in FIG. 16A-16C, the top surface 708 of the module support 700 may be a continuous surface without any opening or, alternatively, a discontinuous surface having openings 720 as shown in dotted lines. The top surface 708 curved along a horizontal axis ‘A1’ which is parallel to the apex line where the front leg 702 of the support 700 joins the rear leg 704. An examplary maximum height ‘H’ of the support at the apex line 706 may be in the range of 4 to 16 inches. An examplary side length S1′ of the support 700 may be in the range of 46 to 84 inches. An edge length ‘E1’ for the front and rear edges of the support may be in the range of 60 to 120 inches. The front and rear edge lengths are preferably the same; however, depending on the solar module design, the dimensions of the support 700 may be changed.

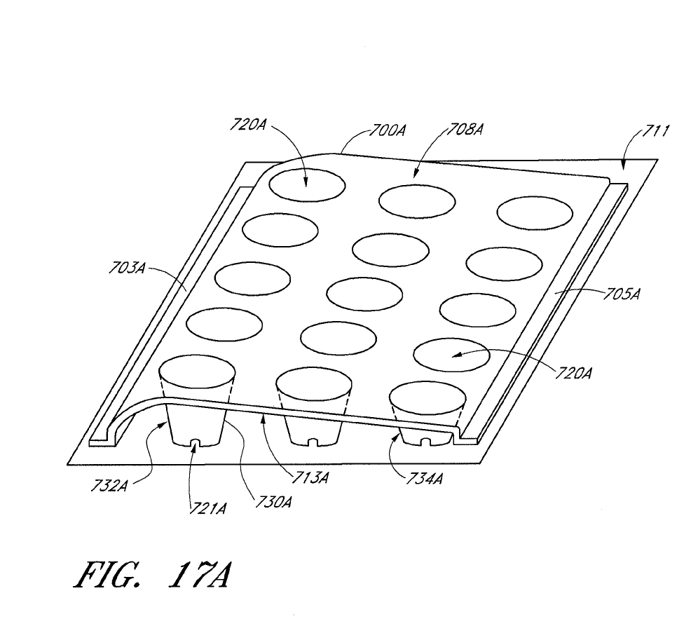

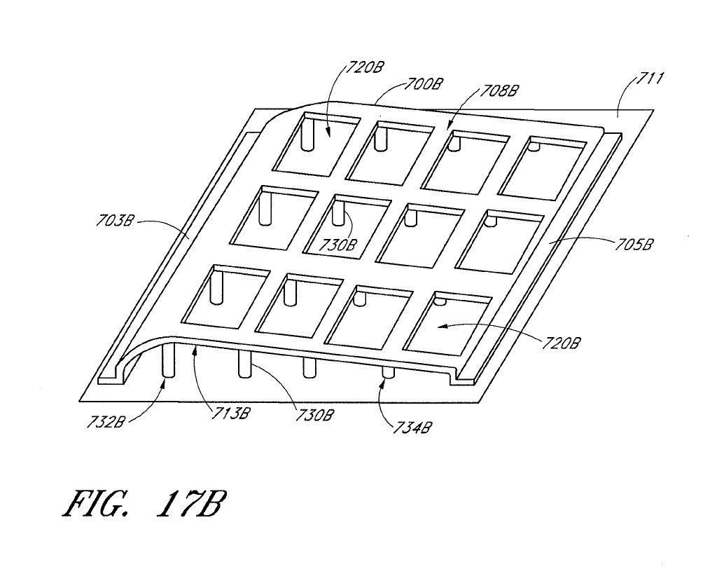

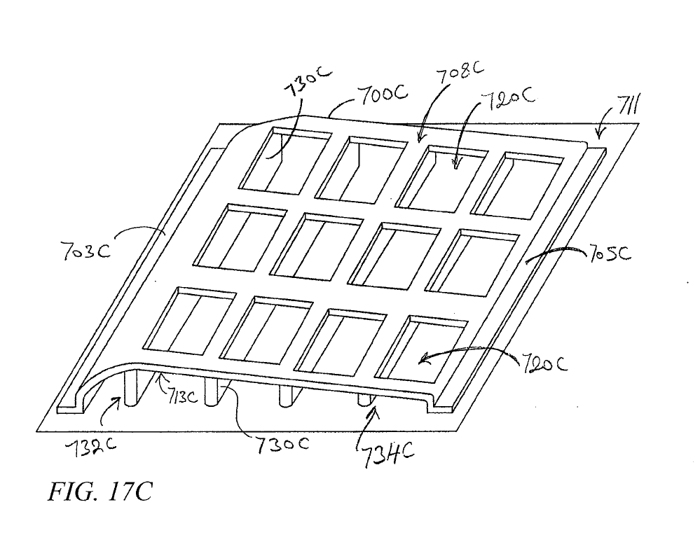

FIGS. 17A-17D show various examplary embodiments for the module support 700 or wedge. Each of module supports 700A, 700B, 700C and 700D has the same curved body shape with additional features such as a number of support members to secure the support on the application surface, water drainage or air flow openings and other features and their combinations thereof.

As shown in FIG. 17A, the support 700A may be supported by rows of support members 730A shaped as recesses or cups. This support design is generally similar to the above described embodiment shown in FIGS. 14A-14C. The support members 730A function as additional legs for the support 700A to further stabilize and secure the assembly on the application surface 711 while advantageously providing air circulation and water drainage. As shown in FIG. 17A, the recesses 730A may have a round or cup shape formed in the top surface 708A extending downwardly from a top opening 720A and may have a bottom opening 721A at the bottom to drain any water. The cup shape of the recesses may have a tapered or straight wall. In an alternative embodiment, the front and rear foot members 703A and 705A may not be needed, and the front and rear edge of the support may be supported and secured on the application surface 711 by a front row 732A and a rear row 734A of the support members 730A. Some of the benefits of this design are: 1) The cup shaped support members create a larger area of contact on the roof and a wider, stronger interface with the surface to distribute the weight of the structure on the roof in the event of snow or from human walking traffic, i.e., to maintain the assemblies; 2) The design allows it to realize the lower tooling costs and material options of being made with vacuum forming or injection molding process.

As shown in FIG. 17B, the support 700B may be supported by rows of support members 730B shaped as round or rectangular columns or legs. The support members 730B may be tapered or straight. This support design is generally similar to the above described embodiment shown in FIGS. 13A-13B with these exceptions: 1) The larger openings under the module and narrower legs allows air to flow under the module with less restriction and therefore at higher speeds which improves cooling of the module, and 2) the design more suited to the material cost benefits of high volume manufacturing that can be yielded from injection molding. The support members 730B function as additional legs for the support 700B to secure it on the application surface 711. Openings 720B in the top surface 708B provides air circulation and water drainage. In an alternative embodiment, the front and rear foot members 703B and 705B may not be needed, the front and rear edge of the support 700B may be supported and secured on the application surface 711 by a front row 732B and a rear row 734B of the support members 730B.

As shown in FIG. 17C, the support 700C may be supported by rows of support members 730C shaped as walls. The support members 730C function as additional legs for the support 700C to secure it on the application surface 711. Openings 720C in the top surface 708C provides air circulation and water drainage. In an alternative embodiment, the front and rear foot members 703C and 705C may not be needed, the front and rear edge of the support 700C may be supported and secured on the application surface 711 by a front row 732C and a rear row 734C of the support members 730C. The supports shown in the above embodiments may be made of polymers or metallic materials may be manufactured readily through extrusion processes, molding processes or other advantageous means such as welding fastening using various fastening means. This design could be manufactured by either injection molding, an optional vacuum forming process, or could be stamped from single pieces of sheet-metal which may have substantial benefits over plastics for strength, longevity, the cooling benefits of better heat conductivity through the bottom of the module, and potentially lower tooling costs.

As shown in FIG. 17D, in another embodiment, the support 700D may be supported by rows of support members 730D shaped as grooves or linear recesses. As in the other embodiments, the support members 730D function as additional legs for the support 700A to further stabilize and secure the assembly on the application surface 711 while providing air circulation and water drainage. As shown in FIG. 17D, the recesses 730D may have a rectangular cup shape formed in the top surface 708D extending downwardly from a top opening 720D and may have bottom openings 721D at the bottom to drain any water. The grooves may have tapered or straight walls. The support members 730D may be shaped as closed ended grooves as shown in FIG. 17D or may be shaped as open ended grooves. In an alternative embodiment, the support members 730D may extend parallel to the front and rear foot members 703A and 705A. The groove shaped support members create a larger area of contact on the roof and a wider, stronger interface with the surface to distribute the weight of the structure on the roof in the event of snow or from human walking traffic, i.e., to maintain the assemblies; 2) The design allows it to realize the lower tooling costs and material options of being made with vacuum forming or injection molding process.

FIG. 18A shows in exploded view another embodiment of module assembly 701 and a method of installing it on the application surface 711. In this embodiment, the module assembly 701 may be attached to the application surface 711 using one or more base elements 750 that include one or more fastening members 752. The application surface 711 may be made of various materials including such as PVC, TPO, EPDM, modified bitumen, metal and the like. As shown in FIGS. 18A-18B, in one embodiment, the base elements 750 may be shaped as a belt that can be bonded to the underlying application surface 711. An examplary thickness for the base elements 750 may be in the range of 1-10 mm, preferably 2-6 mm, and most preferably 3-4 mm. The front and rear foot members 703, 705 of the support can be securely fastened to the base elements 750 using the fastening members 752 secured the base elements. The combination of the base elements 750 and the fastening members 752 provides an advantageous locking mechanism to keep the module assembly 701 on a rooftop without penetrating the underlying roof membrane and structure thereby not damaging the roof seal. Alternatively, either the foot or the base elements may have fastening members to lock or join the foot members 703, 705 and the base elements 750 securely together. In one implementation, the base element may have male fastening member components, such as pins or studs 752, upwardly extending from the base elements 750. During the installation, as the front and rear foot members 703, 705 are positioned on the base elements 750, openings 754 formed along the foot members receive the pins 752, and the foot members 703, 705 butt tightly with the base elements 750. The foot members 703, 705 of the support 700 are secured on the base elements by joining female fastening member components such as nuts 756 with the pins 752 inserted through the receiving holes 754 of the foot members. The nuts 756 may have larger diameter than the receiving holes so as to press down the foot members 703, 705 towards the base elements 750. As the pins 752 and the nuts are coupled, the foot members 703 and 705 are tightly attached to the base elements 750. The pins 752 may have threaded tops to receive the matching threaded hole of nuts 756. Alternatively, nuts may also be ratcheted nuts that can be pressed down on the pins to lock them. Alternatively, a number of nuts 756 can be incorporated in a long structure where the nuts are incorporated as sheet-metal features that lock in one direction onto the pins 752 as they are pressed in place. Once the support 700 is secured on the base elements 750 that are fastened to the application surface 711, the solar module 710 is mounted on the support 700 as described above. In another embodiment, the holes in the foot members 703, 705 may have a particular profile matching the profile of the pins on the base elements, or nuts integrated to the foot members, so that the pins snap-in the holes and fasten the support o the base elements when the support is pressed down on the pins and without a need for separate nuts.

It will be appreciated the above described installation method can be performed with the already assembled support and module; alternatively, the entire module assembly including the base members may be assembled in a manufacturing location and the transported to the application surface and fastened to the application surface.

As shown in FIG. 18B, the pins 752 may be inserted through holes 785 formed in the base element 750. In this inserted configuration, a pin plate 760 attached to the bottom end of the pin 752 rests against a back surface 751B of the pin 752 while the front end of the pin 752 upwardly extends from an upper surface 751A of the base element 750. However, the base element does not need to be a belt or strip including a plurality of pins. Alternatively a base element may not be a continuous elongated piece placed under a foot members, it may be square or rectangular shape smaller belt pieces. For example, in FIG. 18A, there may be three smaller base element pieces under each foot members 703 and 705. Each smaller base element piece may include one pin extending from the piece.

To attach the base elements 750 with the pins to a rooftop, a fast hardening adhesive may be applied to the back surface 751B and the base element is pressed down on the rooftop surface. The base element may be self-adhering base element including a contact adhesive layer disposed to cover the back surface 751A of the base element 750. The contact adhesive layer may be covered with a release film to protect the adhesive during shipping and handling. Alternatively, depending on the application surface material and the base element material, various fastening processes may be used to fasten the base element to the application surfaces. Although not necessary, if the application surface 711 and the base elements 750 are made of the same material, some alternative welding processes may be used to fasten the base element to the application surface. In one implementation both the application surface and the base member may be the same polymer material such as TPO (thermoplastic polyolefin), PVC (polyvinyl chloride), EPDM (ethylene propylene diene monomer) and the like, a hot air weld process may be used to fasten them. For example, if the material of the application surface and the base element is TPO, a hot air welding process may be used to fasten the base element to the application surface 711. The application surface 711 may be a geomembrane, used as a land fill liner or for other containment purposes, made of materials including one of PVC, TPO or EPDM and other materials or their combinations thereof. The base elements for this application are selected from the same material as the geomembrane surface and may be hot air welded or adhesive adhered to the geomembrane surface. The application surface 711 may be made of many industry standard rooftop materials including various asphalt or bitumen base rooftop materials including for example Built Up Rooftop (BUR) surface materials such as any of a modified BUR, a hot BUR or a cold BUR. With such asphalt or bitumen based application surfaces, base elements including asphalt or bitumen so called capsheets may be used. Capsheets are generally asphalt or bitumen impregnated membranes and fastened to a modified BUR surface using open flame torch, to a hot BUR surface using hot asphalt and to a cold BUR surface using an emulsion or mastic cement. If the application surface is concrete, metal or ceramic, base elements may be TPO or PVC and adhered to the application surface using adhesives. For example, a felt back TPO or PVC base element can be adhered to a concrete application surface using adhesives. Table 1 shows some examplary materials used to manufacture various components of the solar assembly and some selected fastening methods and materials.

TABLE 1
Solar Module Assembly Materials and Fastening Method

| Between Application Surface (AS) | | | | | | | | |
|---|---|---|---|---|---|---|---|---|
| and Base Element (BE) | | | Between Base Element (BE) and Support | | | Between Support and Module | | |
| AS | BE | Fastening | BE | Support | Fastening | Support | Module | Fastening |
| Material | Material | Method | Material | Material | Method | Material | Backing | Method |
| TPO | TPO | Hot air | TPO | PET | Mechanical | PET | TEDLAR | Foam tape |
| | | weld | | | | | | |
| PVC | PVC | Hot air | PVC | PET | Mechanical | PET | TEDLAR | Foam tape |
| | | weld | | | | | | |
| EPDM | EPDM | Hot air | EPDM | PET | Mechanical | PET | TEDLAR | Foam tape |
| | | weld | | | | | | |
| Modified | Modified | Open | Modified | PET | Mechanical | PET | TEDLAR | Foam tape |
| BUR | Capsheet | Flame | Capsheet | | | | | |
| | | Torch | | | | | | |
| Hot BUR | Capsheet | Hot | Hot BUR | PET | Mechanical | PET | TEDLAR | Foam tape |
| | | Asphalt | | | | | | |
| Cold BUR | Capsheet | Emulsion | Capsheet | PET | Mechanical | PET | TEDLAR | Foam tape |
| | | or mastic | | | | | | |
| | | cement | | | | | | |
| Geo- | TPO | Hot air | TPO | PET | Mechanical | PET | TEDLAR | Foam tape |
| membrane | | weld | | | | | | |
| Concrete | Felt Back | Fully | Felt Back | PET | Mechanical | PET | TEDLAR | Foam tape |
| | TPO or | Adhered | TPO or | | | | | |
| | PVC | | PVC | | | | | |

The material of the base element 750 may be readily rolled up for transport and storage, and installed on an application surface or structure by cutting it to a predetermined length; inserting pins through the holes; applying the adhesive or releasing the release film if the self adhesive layer is included; attaching the base elements to the application surface in a desired array, determined by the dimensions of the support 700, by applying pressure to bond them to the application surface, securing the module assembly on the base elements as described above; and finally completing the installation by connecting the electrical terminals to a power circuit.

Materials of the assembly components may be materials used in the roofing industry for low slope, membrane style roofs such as those used on commercial rooftops. Some examplary materials for the base elements or belts may be TPO, EDPM, AND PVC and other built up materials manufactured by such companies as John's Manvile, GAF, Firestone, Atlas, Carlisle, and others. Such base elements can be as narrow as 4″ wide and as wide as 16″ wide. Pins and nuts would be made of materials suitable for long term to exposure typical of rooftops such as Galvanized Steel, Zinc Plated Steel, Cadmium plated Steel, Stainless Steels of several varieties. Module supports described above may be made of various strong machinable aluminum materials such as 6061, 5052, 2024 with various finishing methods such as alodine, anodizing, or zinc plating and UV stabilized plastics such as polycarbonate, high molecular weight polyethelynes, UV stabilized polyproplyenes, ABS plastics, UV resistant PVC plastics, and other hard strong plastics suitable for roof top conditions. Adhesives that may be used are Butyls, silicones, resin, acrylic, and cyanacrylate materials common in construction for bonding materials for long term exposure in roof top and outdoor applications. The adhesive materials could also be two parts consisting of foam strips that are separately bonded to the support and the module then are bonded together. These adhesive strips could also be a combination of a strip of adhesive material in combination with material that does not contain adhesive but is proven to provide a strong bond with the adhesive material. Such a combination of materials might be materials commonly used to bond windows in skyscrapers where one surface of the adhesive bonds to aluminum or glass, while the other might bond to any of several types of plastic such as those discussed prior. Some manufactures that make materials suitable for this applications are 3M, Saint-Gobain, Shnee-Morehead, Henkel, among others. Another option for bonding the panel to the structure would be to halves of a separable fastening material such as hook and loop or mushroom cup materials available from 3M among others and bonding both sides to the module and structure separately at the manufacturing facility and doing final attachment of the materials in the field. This method may prove to make assembly faster and allow the panel to remove from the structure without damaging the adhesive.

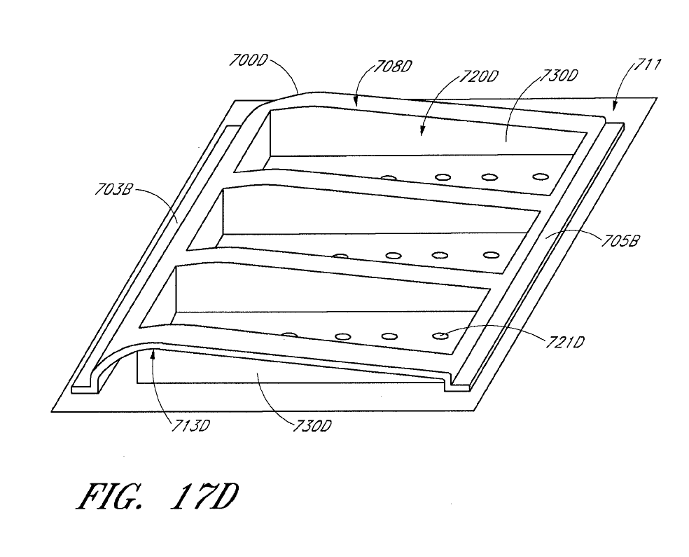

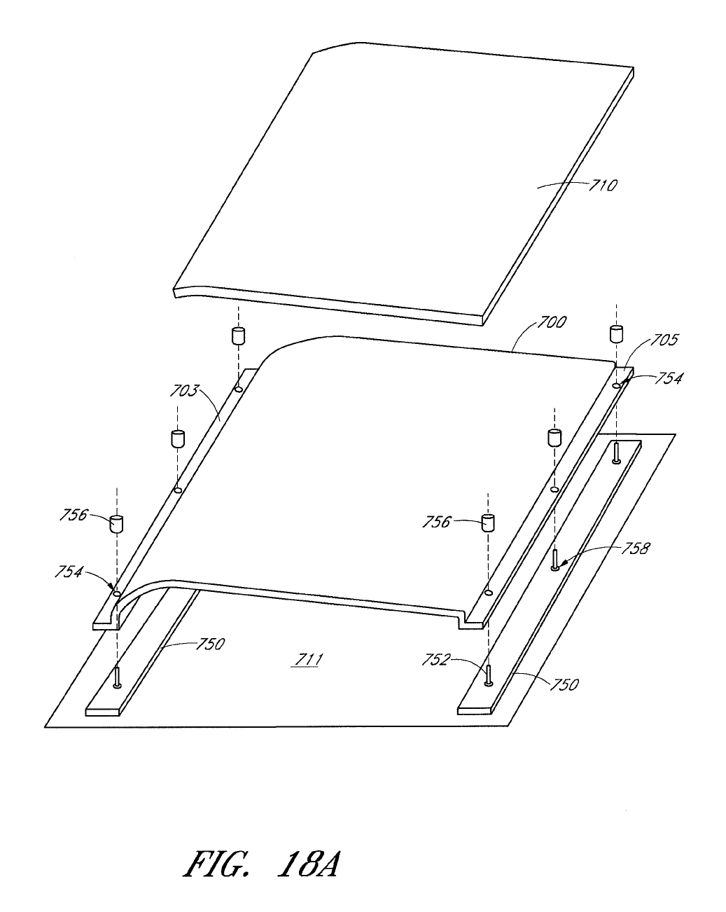

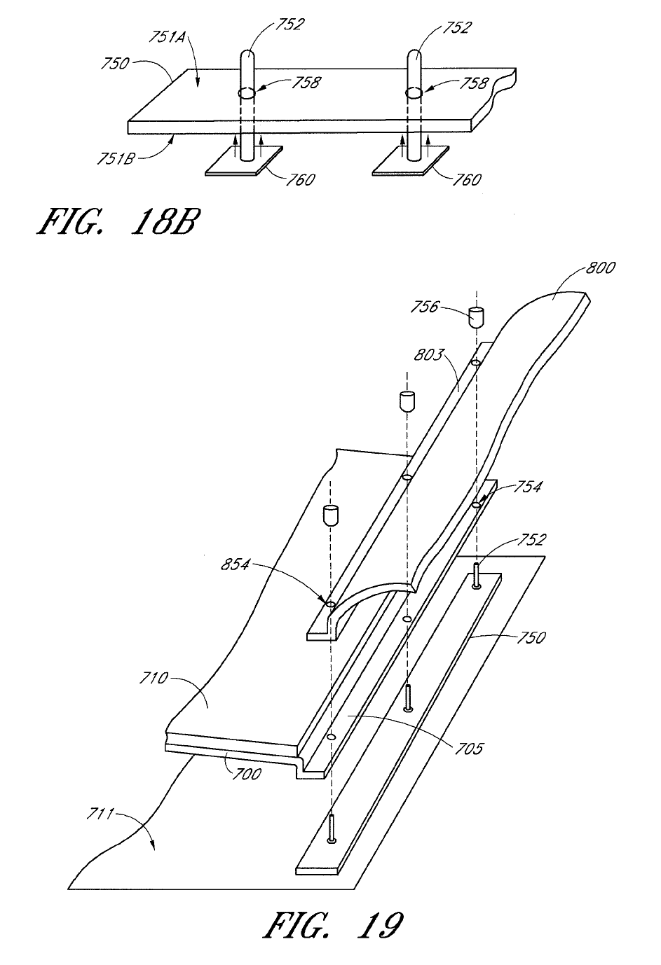

With the above described system, a series of module assemblies may be secured on the same base element and share the same base element. As shown in FIG. 19, in a partial exploded view, the rear foot member 705 of the support 700 and a front foot 803 of another support 800 may be secured to the same base element 752, by overlapping the rear foot member 705 and the front foot member 803 and fastening them to the base element as described above. The rear foot member 705 and the front foot member 803 have the same pin receiving hole pattern. It will be appreciated that the above described method of installation, which the same base elements is shared by two module supports by overlapping the rear foot member of one support and the front foot member of another and fastening them to the base element, may be applicable to the previous described curved or angled assembly embodiments described through 2-14 above as well as to planar top such as flat or slanted top assembly designs that support a module in a manner parallel to the application surface or angled manner. Such slanted top or flat top assembly designs may have a module support with a planar top surface having an elevated configuration to maintain the module elevation off the application surface, such as a roof deck, to allow air and water flow through it. Such planar assembly designs may have the similar or same foot members described for the above embodiments.

FIG. 20 shows an multi module assembly array including module assemblies 801A having a support 800A and a module 810A; 801B having a support 800B and a module 810B; 801C having a support 800C and a module 810C; and 801D having a support 800D and a module 810D. The module assemblies 801A-801D are secured to the application surface 711 by the base elements 750A, 750B and 750C. In this array, particularly the rear foot member of support 800A and the front foot member of support 800B overlap and secured by the base element 750B as well as the rear foot member of support 800C and the front foot member of support 800D overlap and secured by the same base element 750B. Using this principle, the module assembly array can be expanded side ways, backward or forward directions by adding new module assemblies. The array may be form without any gap between the assembly pairs 801A-801B and 801C-801D. Each base element 750A, 750B and 750C may be a continuous single piece base element as shown in FIG. 20, or discontinuous multi piece base elements. For example the assembly pairs 801A-801B may be secured to a first array of 3 three base member while the assembly pairs 801C-801D may be secured to a second array of another three base members, and so on.

In the event that a module fails, the modules can be removed from the mounting structure by separating the material through common methods. If the module is mounted using a hook and look type system the module can simply be separated and replaces. In the event that the roof needs to be replaced, the structure can be removed from the roofing substrate easily by removing the nuts and bolt plates and saving the array and panels intact for replacement after roof material is replaced. .

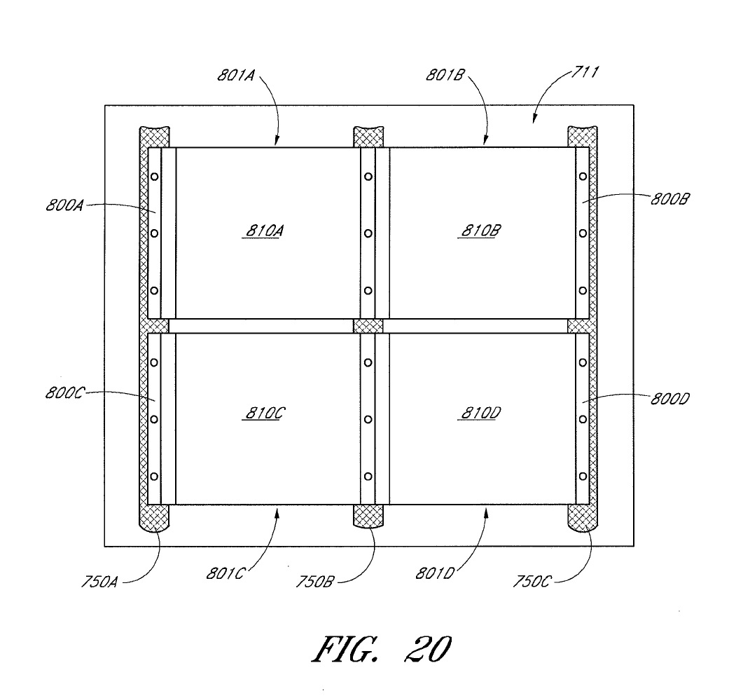

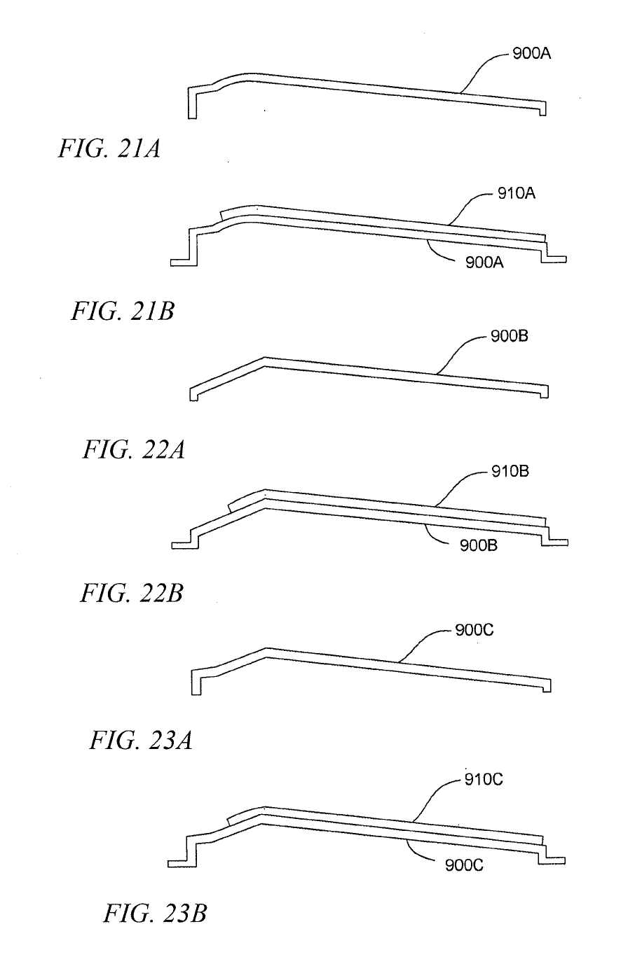

FIGS. 21A-23B show various module support and module assembly profile examples. As shown in FIG. 21A 21B, a module support 900A may have a minor and major surfaces and the minor surface may have a curved and flat minor surface portions. A module 910A is fastened to the partially curved minor surface portion and the major surface. As shown in FIGS. 22A and 22B, the major and minor surfaces of a module support 900B are angled and a module 910B is fastened to the minor surface and major surface. As shown in FIGS. 23A-23B, a module support 900C may have a minor and major surfaces and the minor surface may have an angled minor surface portions. A module 910C is fastened to one of the angled minor surface portion and the major surface.

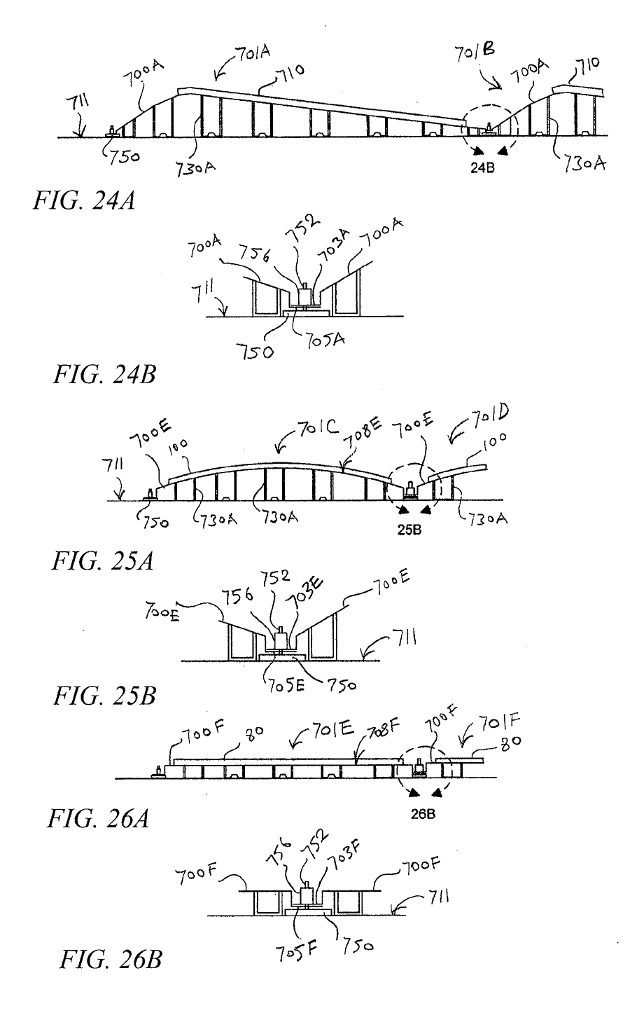

FIGS. 24A and 24B show module assemblies 701A and 701B using the embodiment shown in FIG. 17A, where the support 700 includes round cup shaped recesses as support member 730A as described above, or alternatively the grooves 730D as shown in FIG. 17D. If the grooves 730D are used as support members, the grooves extend parallel to the front and rear foot members 703A and 705A. The supports 700A of the module assemblies are fastened to the application surface as described above with respect to FIGS. 18A and 19. As shown in FIG. 24B in detail view, the rear foot member 705A of the module assembly 701A and the front foot member 703A of the module assembly 701B are fastened to the application surface 711 using the base element 750, pin 752 and nut 756 as described above.

FIGS. 25A and 25B show module assemblies 701C and 701D using the supports 700E including round cup shaped recesses as support member 730A as described above or alternatively the grooves 730D as shown in FIG. 17D. If the grooves 730D are used, the grooves extend parallel to the front and rear foot members 703A and 705A.As shown, in this embodiment the supports 700E have symmetrical saddle shape top surface 708E as described through FIGS. 2-14C. The solar modules 100 are secured on the top surfaces of the module supports 700E. The supports 700E include front and rear foot members 703E and 705E to fasten them to the application surface 711. The supports 700E of the module assemblies are fastened to the application surface 711 as described above with respect to FIGS. 18A and 19. As shown in FIG. 25B in detail view, the rear foot member 705E of the module assembly 701C and the front foot member 703E of the module assembly 701D are fastened to the application surface 711 using the base element 750, pin 752 and nut 756 as described above.

FIGS. 26A and 26B show module assemblies 701E and 701F using the supports 700F including round cup shaped recesses as support member 730A as described above or alternatively the grooves 730D as shown in FIG. 17D. If the grooves 730D are used, the grooves extend parallel to the front and rear foot members 703F and 705F. The grooves 730D may have the same elongated shape and the same depth. As shown, in this embodiment the supports 700F have a planar or flat top surface 708F. The solar modules 80 are secured to the planar top surfaces of the module supports 700F. The supports 700F include front and rear foot members703E and 705E to fasten them to the application surface 711. The supports 700F of the module assemblies are fastened to the application surface 711 as described above with respect to FIGS. 18A and 19. As shown in FIG. 26B in detail view, the rear foot member 705F of the module assembly 701E and the front foot member 703F of the module assembly 701F are fastened to the application surface 711 using the base element 750, pin 752 and nut 756 as described above.

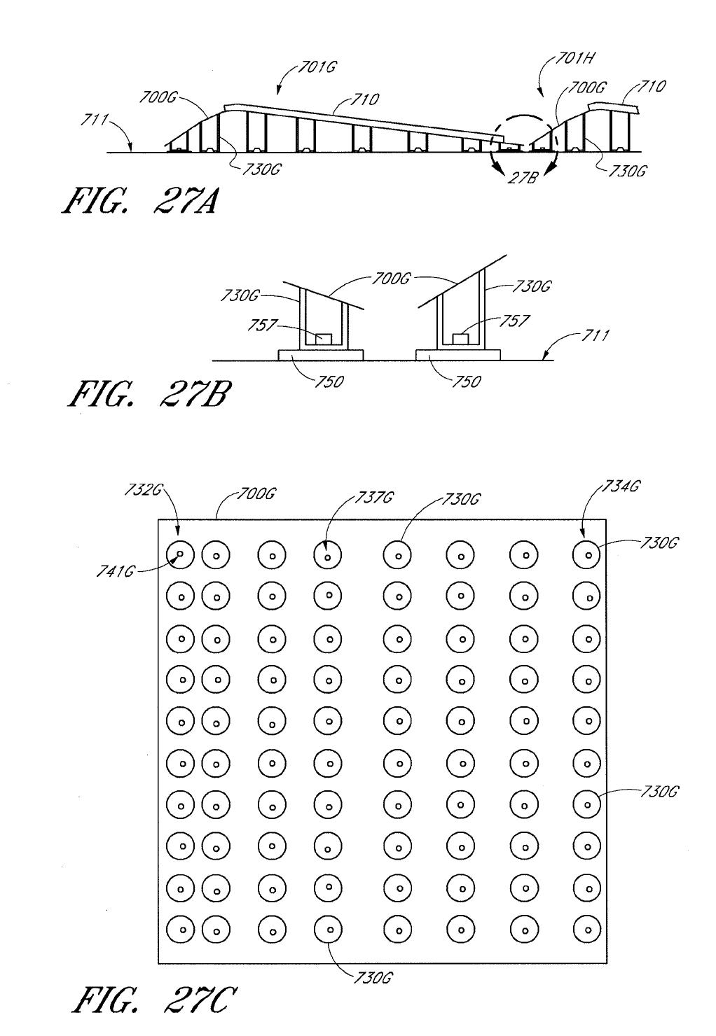

FIGS. 27A-27C illustrate module assembly 701G using module support 700G which is an embodiment of the module support 700A shown in FIG. 17A or the module support 700D shown in FIG. 17D. For example, the module support 700G includes support members 730G that are similar to round cup shaped support members described above in FIG. 17A or alternatively the groove shaped support members 730D described in FIG. 17D. In this embodiment, the support 700G is fastened to the application surface 711 using a front row 732G and a rear row 734G of the round cup shaped support members 730G, shown in FIG. 27C in top view. FIGS. 27A-27B also show another module assembly 701H adjacent the module assembly 701G. The support members 730G can also include bottom openings 741G to facilitate draining of moisture. Moreover, the support members 730G include top openings 720G that extend across the width of the support 700G. These openings 720G provide both cooling to the module 710 but can also be used for routing cabling and the like across the module assemblies.

As discussed previously, the module assembly 701G can be secured to the application surface 711, e.g., a roof, wall or the like, via the previously described fasteners. As shown in FIGS. 27B and 27C, alternatively, clips 757 extending from the base elements 750 can be inserted through openings 741G formed at the bottom of the support members 730G of the front and rear rows 732G and 744G. By securing the clips in the recesses of the support members 730G, the supports 700G are better secured on the application surface 711 as the clips do not protrude where they could be dislodged by inadvertent contact.

Although aspects and advantages of the present inventions are described herein with respect to certain preferred embodiments, modifications of the preferred embodiments will be apparent to those skilled in the art. Thus the scope of the present inventions should not be limited to the foregoing discussion, but should be defined by the appended claims.

What is claimed is:

1. A method of installing a rooftop solar system on a roofing surface comprising:
affixing an array of base elements including a plurality of fastening members to the roofing surface;
engaging feet of a module support with the plurality of fastening members of base elements so as to fasten the module support to the base elements on the roofing surface, wherein the module support having a top surface that is convexly curved or angled along a longitudinal axis of the top surface, and wherein the top surface including a major surface portion that is generally separated from a minor surface portion along the longitudinal axis of the top surface; and
attaching a flexible solar module onto the top surface of the module support, the flexible module having a plate like body defined by a top transparent layer disposed over a bottom layer, wherein the bottom layer of the solar module is in physical contact with and is substantially supported by the top surface of the module support by covering the major surface and
partially covering the minor surface of the top surface so as to leave an exposed access space on the minor surface.

2. The method of claim 1, wherein the engaging feet comprises engaging a plurality of male fastening members of the base elements with the plurality of female fastening members of the module support.

3. The method of claim 2, wherein the feet are provided with a plurality of opening members to receive the plurality of fastening members.

4. The method of claim 1, wherein affixing an array of base elements comprises affixing the bases elements to the roofing surface using an adhesive.

5. The method of claim 1, wherein the roofing surface comprises providing a generally planar surface outside a building structure.

6. The method of claim 5, wherein the roofing surface comprises at least one of PVC, TPO, EPDM, modified bitumen materials.

7. The method of claim 4, wherein the adhesive comprises at least one of TPO, PVC, or EPDM.

8. A solar module assembly installed on an application surface, comprising:
at least two base elements affixed to the application surface, the base elements including a bottom surface and an upper surface, wherein the upper surface includes a plurality of fastening members;
a module support fastened to the base elements by engaging feet of the module support with the plurality of fastening members, the module support having a top surface that is convexly curved or angled along a longitudinal axis of the top surface, wherein the top surface including a major surface portion that is generally separated from a minor surface portion along the longitudinal axis of the top surface; and
a flexible solar module attached onto the top surface of the module support, the flexible module having a plate like body defined by a top transparent layer disposed over a bottom layer, wherein the bottom layer of the solar module is in physical contact with and is substantially supported by the top surface of the module support by covering the major surface and partially covering the minor surface of the top surface so as to leave and exposed access space on the minor surface.

9. The assembly of claim 8, wherein the bottom surface of the base elements includes an adhesive layer and the base elements are affixed to the application surface by the adhesive.

10. The assembly of claim 8, wherein the base elements have belt shape.

11. The assembly of claim 10, wherein the base elements area made of one of TPO, PVC, EPDM and a bitumen impregnated membrane.

12. The assembly of claim 10, wherein a thickness of the base elements is in the range of 1-4 mm.

13. The assembly of claim 8, wherein the feet of the module support are provided with a plurality of fastener receiving openings.

14. The assembly of claim 8, wherein the fastening members are pins received by the fastener receiving opening at the feet of the module support and locked in place by locking nuts.

15. The assembly of claim 8, wherein the module support includes a plurality of support members supporting the module on the application surface.

16. The assembly of claim 15, wherein the support members are depressions in the top surface extending downwardly towards the application surface.

17. The assembly of claim 16, wherein the depression are cylindrical.

18. The assembly of claim 17, wherein the depressions are tapered towards their bottom.

19. The assembly of claim 8, wherein the top surface is a continuous surface without any openings.

20. The assembly of claim 8, wherein the top surface is a discontinuous surface with openings.

21. The assembly of claim 8, wherein the top surface is a discontinuous surface with openings.

22. The assembly of claim 21, wherein the discontinuous surface is supported by support members extending downwardly towards the application surface.

23. The assembly of claim 22, wherein the support members are columns.

24. The assembly of claim 22, wherein the support members are walls extending between the edges of the module support.

25. A solar module assembly comprising:
a first module support member that defines a support surface having a length and a lateral width that is adapted to be positioned on a mounting surface, wherein the first support member extends outward from the mounting surface and wherein the support member is shaped so as to define a first elevated surface and a second elevated surface that intersect at an apex defining the height of the elevated surfaces;
a first flexible solar module that is mounted on the first support member so as to extend over at least some of the first elevated surface; and
a securing assembly that secures the first module support member to the mounting surface.

26. The assembly of claim 25, wherein the first elevated surface has a first length and the second elevated surface has a second length that is less than the first length.

27. The assembly of claim 25, wherein the first elevated surface and the second elevated surface comprise a uniformly curved surface having an apex at approximately the center of the curved surface.

28. The assembly of claim 25, wherein the first module support member includes a first and a second foot member that is mounted on the mounting surface and is secured thereto.

29. The assembly of claim 28, wherein recesses are formed in the first and second foot members to accommodate fasteners to secure the first module support member to the mounting surface.

30. The assembly of claim 25, wherein the first module support member defines openings in the support surface that receives the first flexible solar module to provide cooling to the first flexible solar module.

31. The assembly of claim 30, wherein the openings define channels that extend across the lateral width of the support surface.

32. The assembly of claim 30, wherein the openings define apertures that extend through the support surface.

33. The assembly of claim 25, wherein the first module support member include support protrusions that engage with the mounting surface to provide support to the support surface.

34. The assembly of claim 33, wherein the support protrusions comprise spaced apart columns.

35. The assembly of claim 34, wherein the support columns are hollow and have openings to facilitate the draining of water from the support surface of the first support member.

36. The assembly of claim 33, wherein the support protrusions comprise members that extend across the lateral width of the first support member.

37. The assembly of claim 25, wherein the first flexible solar module is partially mounted on the second elevated surface so as to define an exposed access space.

38. The assembly of claim 25, wherein the securing assembly comprises at least one base element secured to the mounting surface and fasteners that interconnect the at least one base element and the first support member.

39. The assembly of claim 38, wherein the at least one base element comprises a first and a second base element that are positioned adjacent a first and a second edge of the first support member.

40. The assembly of claim 30, wherein the fasteners comprise protrusions that extend outward from the base member that extend through openings in the first support member and couplers that couple to the portion of the protrusions that extend through the first support member to secure the first support member to the base member.

41. The assembly of claim 40, wherein the fasteners are selected from the group consisting essentially of nuts, pins, bolts and clips.

42. The assembly of claim 38, further comprising:
a second module support member that is adapted to be positioned on a mounting surface, wherein the second module support member extends outward from the mounting surface and wherein the second module support member is shaped so as to define a first elevated surface and a second elevated surface that intersect at an apex defining the height of the elevated surfaces;
a second flexible solar module that is mounted on the second module support member so as to extend over the first elevated surface.

43. The assembly of claim 42, wherein fasteners from at least one base member extend through the first and the second module support member to secure both the first and the second module support member to the mounting surface.

44. The assembly of claim 43, wherein the at least one base member is adhered to the mounting surface.

45. The assembly of claim 44, wherein the at least one base member is belt shaped and has an adhesive layer.

46. A solar module assembly comprising:
a first module support member that defines a support surface with an elevated surface having a length and a lateral width that is adapted to be positioned on a mounting surface, wherein the first support member extends outward from the mounting surface;
a first flexible solar module that is mounted on the first support member so as to extend over at least one of the first elevated surface;
a securing assembly that secures the first support member to the mounting surface wherein the first module support member has first and second foot members at the ends of the first module support member that secure the first support member to the mounting surface; and
a plurality of support members that engage with the first module support member so as to extend between the first module support member and the mounting surface, wherein the plurality of support members extend in rows across the lateral width of the elevated surface.

47. The assembly of claim 46, wherein the plurality support members comprise round cup shaped recesses formed into the first module support member.

48. The assembly of claim 47, wherein the plurality of support members have substantially the same height.

49. The assembly of claim 47, wherein the plurality of support members comprise a plurality of grooves that extend across the width of the first module support member and have substantially the same size.

50. The assembly of claim 46, wherein the first module support member defines a curved support surface having an apex.

51. The assembly of claim 46, further comprising a second module support member that defines a support surface with an elevated surface having a length and a lateral width that is adapted to be positioned on the mounting surface, wherein the second support member extends outward from the mounting surface wherein the second module support member has a first and second foot member at the ends of the second module support member;
a second flexible solar module that is mounted on the first support member so as to extend over at least one of the first elevated surface; and
wherein the securing assembly engages with a first foot of the first module support member and a first foot of the second module member to secure the first and second module support members to the mounting surface.
